(19) United States
(12) Patent Application Publication
(10) Pub. No.: US 2025/0293478 A1
(43) Pub. Date: Sep. 18, 2025

(54) CHAMBER APPARATUS FOR LASER, GAS LASER APPARATUS, AND ELECTRONIC DEVICE MANUFACTURING METHOD

(71) Applicant: Gigaphoton Inc., Tochigi (JP)

(72) Inventor: Rei TAKENAKA, Oyama-shi (JP)

(73) Assignee: Gigaphoton Inc., Tochigi (JP)

(21) Appl. No.: 19/047,019

(22) Filed: Feb. 6, 2025

(30) Foreign Application Priority Data
Mar. 18, 2024 (JP) 2024-042421

(51) Int. Cl. H01S 3/134; H01S 3/036; H01S 3/038

(52) U.S. Cl. CPC H01S 3/134; H01S 3/0381; H01S 3/0382; H01S 3/036

(57) ABSTRACT

A chamber apparatus for a laser configured to output laser light, the chamber apparatus including: a chamber; a first discharge electrode disposed in an internal space of the chamber and having a longitudinal direction aligned with an optical axis of the laser light; a second discharge electrode so disposed in the internal space that the second discharge electrode faces the first discharge electrode and has a longitudinal direction aligned with the optical axis of the laser light; a return member electrically connected to the chamber and further electrically connected to the second discharge electrode over a length from one end to the other end thereof in the longitudinal direction; and a support member fixed to the chamber and supporting the second discharge electrode, the second discharge electrode and the chamber being not electrically continuous with each other via the support member.

### CROSS-REFERENCE TO RELATED APPLICATIONS

The present application claims the benefit of Japanese Patent Application No. 2024-042421, filed on Mar. 18, 2024, the entire contents of which are hereby incorporated by reference.

### BACKGROUND

### 1. Technical Field

The present disclosure relates to a chamber apparatus for a laser, a gas laser apparatus, and an electronic device manufacturing method.

### 2. Related Art

In recent years, semiconductor exposure apparatuses are required to improve the resolution thereof as semiconductor integrated circuits are increasingly miniaturized and highly integrated. To this end, reduction in the wavelength of light output from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from KrF and ArF excimer laser apparatuses that perform spontaneous oscillation has a wide spectral linewidth ranging from 350 to 400 pm. A projection lens made of a material that transmits ultraviolet light, such as KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (such as etalon and grating) is provided in some cases in a laser resonator of the gas laser apparatus to narrow the spectral linewidth. A gas laser apparatus providing a narrowed spectral linewidth is hereinafter referred to as a narrowed-line gas laser apparatus.

### CITATION LIST

### Patent Literature

[PTL 1] JP-A-4-5877

### SUMMARY

A chamber apparatus for a laser according to an aspect of the present disclosure may be a chamber apparatus for a laser configured to output laser light, the chamber apparatus including: a chamber body; a first discharge electrode disposed in an internal space of the chamber body and having a longitudinal direction aligned with an optical axis of the laser light; a second discharge electrode so disposed in the internal space that the second discharge electrode faces the first discharge electrode and has a longitudinal direction aligned with the optical axis of the laser light; a return member electrically connected to the chamber body and further electrically connected to the second discharge electrode over a length from one end to the other end thereof in the longitudinal direction; and a support member fixed to the chamber body and supporting the second discharge electrode, the second discharge electrode and the chamber body being not electrically continuous with each other via the support member.

A gas laser apparatus according to another aspect of the present disclosure may be a gas laser apparatus including a chamber apparatus for a laser configured to output laser light, the chamber apparatus for a laser including a chamber body, a first discharge electrode disposed in an internal space of the chamber body and having a longitudinal direction aligned with an optical axis of the laser light, a second discharge electrode so disposed in the internal space that the second discharge electrode faces the first discharge electrode and has a longitudinal direction aligned with the optical axis of the laser light, a return member electrically connected to the chamber body and further electrically connected to the second discharge electrode over a length from one end to the other end thereof in the longitudinal direction, and a support member fixed to the chamber body and supporting the second discharge electrode, the second discharge electrode and the chamber body being not electrically continuous with each other via the support member.

An electronic device manufacturing method according to another aspect of the present disclosure may include outputting laser light generated by a gas laser apparatus to an exposure apparatus; and exposing a photosensitive substrate to the laser light in the exposure apparatus to manufacture electronic devices, the gas laser apparatus so configured that a chamber apparatus for a laser configured to output the laser light includes a chamber body, a first discharge electrode disposed in an internal space of the chamber body and having a longitudinal direction aligned with an optical axis of the laser light, a second discharge electrode so disposed in the internal space that the second discharge electrode faces the first discharge electrode and has a longitudinal direction aligned with the optical axis of the laser light, a return member electrically connected to the chamber body and further electrically connected to the second discharge electrode over a length from one end to the other end thereof in the longitudinal direction, and a support member fixed to the chamber body and supporting the second discharge electrode, the second discharge electrode and the chamber body being not electrically continuous with each other via the support member.

### BRIEF DESCRIPTION OF DRAWINGS

Embodiments of the present disclosure will be described below only by way of example with reference to the accompanying drawings.

FIG. 1 is a diagrammatic view showing a schematic configuration example of an entire electronic device manufacturing apparatus.

FIG. 2 is a diagrammatic view showing a schematic configuration example of an entire gas laser apparatus according to Comparative Example.

FIG. 3 is a cross-sectional view of a chamber apparatus according to Comparative Example taken along a plane perpendicular to an optical axis of laser light.

FIG. 4 is a descriptive diagram showing how a ground plate and a chamber body are positioned.

FIG. 5 is a descriptive diagram showing how a second discharge electrode and the ground plate are positioned.

FIG. 6 shows a return member.

FIG. 7 is a cross-sectional view of the chamber apparatus in Comparative Example taken along a plane parallel to the optical axis of the laser light.

FIG. 8 is a cross-sectional view of a chamber apparatus according to a first embodiment taken along a plane parallel to the optical axis of the laser light.

FIG. 9 is a cross-sectional view of a chamber apparatus according to a second embodiment taken along a plane parallel to the optical axis of the laser light.

FIG. 10 is a cross-sectional view of the chamber apparatus according to the second embodiment taken along a plane perpendicular to the optical axis of the laser light.

FIG. 11 shows how the second discharge electrode, a placement member, and a support member are positioned.

### DETAILED DESCRIPTION

1. Description of electronic device manufacturing apparatus used in electronic device exposure step
2. Description of Comparative Example
2.1 Configuration
2.2 Operation
3. Problems
4. Description of first embodiment
4.1 Configuration
4.2 Effects and advantages
5. Description of second embodiment
5.1 Configuration
5.2 Effects and advantages

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same elements have the same reference characters, and no redundant description of the same elements will be made.

### 1. Description of Electronic Device Manufacturing Apparatus Used in Electronic Device Exposure Step

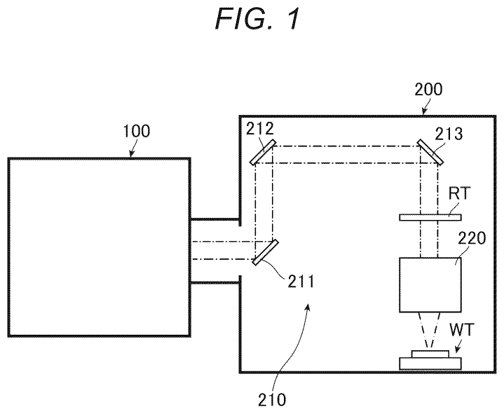

FIG. 1 is a diagrammatic view showing a schematic configuration example of an entire electronic device manufacturing apparatus used in an electronic device exposure step. The manufacturing apparatus used in the exposure step includes a gas laser apparatus 100 and an exposure apparatus 200, as shown in FIG. 1. The exposure apparatus 200 includes an illumination optical system 210, which includes multiple mirrors 211, 212, and 213, and a projection optical system 220. The illumination optical system 210 illuminates a reticle pattern on a reticle stage RT with laser light incident thereon from the gas laser apparatus 100. The projection optical system 220 performs reduction projection on the laser light having passed through the reticle to bring the laser light into focus on a workpiece that is not shown but is placed on a workpiece table WT. The workpiece is a photosensitive substrate onto which a photoresist has been applied, such as a semiconductor wafer. The exposure apparatus 200 translates the reticle stage RT and the workpiece table WT in synchronization with each other to expose the workpiece to the laser light having reflected the reticle pattern. Semiconductor devices that are electronic devices can be manufactured by transferring a device pattern onto the semiconductor wafer in the exposure step described above.

### 2. Description of Comparative Example

### 2.1 Configuration

The gas laser apparatus 100 according to Comparative Example will be described. Comparative Example in the present disclosure is a form that the applicant is aware of as known only by the applicant, and is not a publicly known example that the applicant is self-aware of.

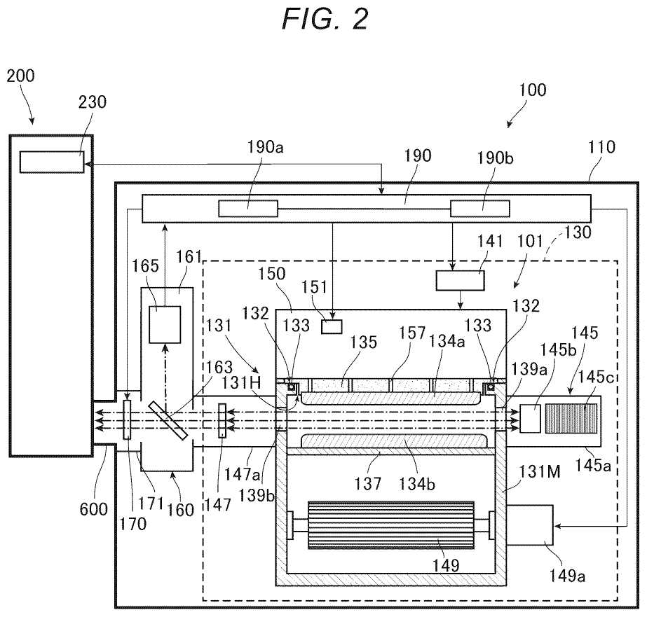

FIG. 2 is a diagrammatic view showing a schematic configuration example of the entire gas laser apparatus 100 according to Comparative Example. The gas laser apparatus 100 is an ArF excimer laser apparatus using a mixture gas containing, for example, argon (Ar), fluorine (F₂), and neon (Ne). The gas laser apparatus 100 outputs laser light having a center wavelength of about 193 nm. Note that the gas laser apparatus 100 may instead be a gas laser apparatus other than the ArF excimer laser apparatus, for example, a KrF excimer laser apparatus using a mixture gas containing krypton (Kr), F₂, and Ne. In this case, the gas laser apparatus 100 outputs laser light having a center wavelength of about 248 nm. The mixture gas containing Ar, F₂, and Ne, which are laser media, and the mixture gas containing Kr, F₂, and Ne, which are laser media, are each called a laser gas in some cases.

The gas laser apparatus 100 includes an enclosure 110, a laser oscillator 130, a monitor module 160, a shutter 170, and a laser processor 190 as primary elements, as shown in FIG. 2. In the following description, the left side of the plane of view along the laser light traveling direction may be referred to as a front side, the right side as a rear side, the upper side as an upper side, and the lower side as a lower side.

The laser oscillator 130 includes a chamber apparatus for a laser 101, a charger 141, a line narrowing module 145, an output coupling mirror 147, and a pulse compression circuit 150 as primary elements. Note in the following description that the chamber apparatus for a laser 101 may be simply referred to as a chamber apparatus 101. FIG. 2 shows the internal configuration of the chamber apparatus 101 in a cross-sectional view taken along the plane containing an optical axis of the laser light.

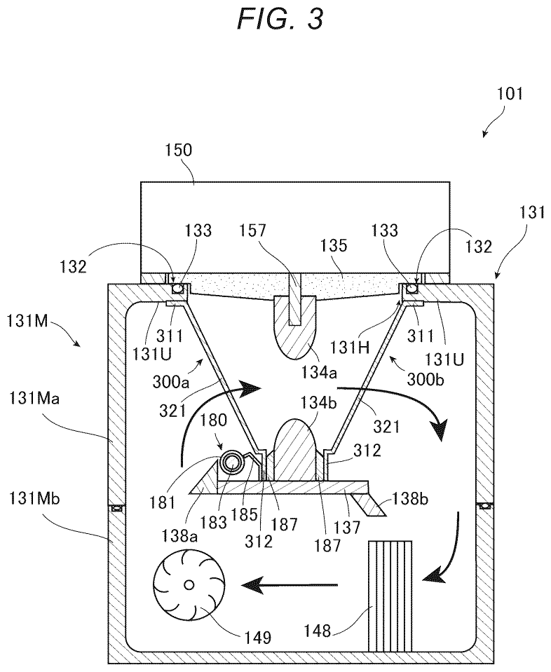

FIG. 3 is a cross-sectional view of the chamber apparatus 101 taken along a plane perpendicular to the optical axis of the laser light. The chamber apparatus 101 includes a discharge chamber 131. The discharge chamber 131 encloses an internal space where the laser medium in the laser gas is excited by discharge that will be described later to generate light. The discharge chamber 131 of the chamber apparatus 101 in the present example includes a chamber body 131M and an electrically insulating plate 135 serving as a lid, as shown in FIGS. 2 and 3. The chamber body 131M is made of an electrically conductive material, for example, nickel-plated aluminum or nickel-plated stainless steel.

An opening 131H is provided in a top wall 131U of the chamber body 131M. The opening 131H is closed by the electrically insulating plate 135. Specifically, a metal seal 133 is disposed in a groove 132 formed in the upper surface of the chamber body 131M, and is so pressed by the electrically insulating plate 135 that the metal seal 133 is deformed. The metal seal 133 therefore functions not to create a space between the chamber body 131M and the electrically insulating plate 135. The chamber body 131M and the electrically insulating plate 135 are thus combined with each other to enclose the internal space of the discharge chamber 131. The internal space is filled with the laser gas.

The electrically insulating plate 135 includes an insulator. The electrically insulating plate 135 may be made, for example, of an aluminum oxide ceramic material, which has low reactivity with F₂ gas. Note that the electrically insulating plate 135 only needs to be electrically insulating, and examples of the material of the electrically insulating plate 135 may include resin such as phenol resin and fluororesin, quartz, and glass.

In the internal space of the discharge chamber 131, a first discharge electrode 134a, and a second discharge electrode 134b are so disposed that the electrodes face each other with a distance therebetween, and that the longitudinal direction of each of the electrodes extends along a predetermined direction that is the direction of the optical axis of the laser light. In the present example, the first discharge electrode 134a is located directly above the second discharge electrode 134b. The first discharge electrode 134a and the second discharge electrode 134b are electrodes that produce glow discharge to excite the laser medium. In the present example, the first discharge electrode 134a is the cathode, and the second discharge electrode 134b is the anode.

A ground plate 137 extends in the optical axis direction of the laser light, and is fixed to the rear and front inner walls of the chamber body 131M. The second discharge electrode 134b is disposed on the ground plate 137, which is a support member that supports the second discharge electrode 134b. In the present example, the ground plate 137 is electrically conductive and is electrically connected to the second discharge electrode 134b.

Spacers 187 are fixed to the opposite ends of the second discharge electrode 134b in the direction perpendicular to the longitudinal direction thereof. The spacers 187 are made of an electrically conductive material and electrically connected to the ground plate 137 and the second discharge electrode 134b. The spacers 187 may be made, for example, of porous nickel metal that has low reactivity with the laser gas.

A return member 300a is connected to a side of one of the spacers 187 that is the side opposite to the second discharge electrode 134b, and a return member 300b is connected to a side of the other spacer 187 that is the side opposite to the second discharge electrode 134b. The return members 300a and 300b are electrically conductive members. The spacers 187 each extend from one end to the other end of the second discharge electrode 134b in the longitudinal direction. An end of each of the return members 300a and 300b that faces the second discharge electrode 134b also extends along the longitudinal direction of the second discharge electrode 134b from the one longitudinal end to the other longitudinal end of the second discharge electrode 134b.

The second discharge electrode 134b is in contact with the spacers 187 along the longitudinal direction described above, and the spacers 187 are in contact with the return members 300a and 300b along the longitudinal direction described above. The second discharge electrode 134b is therefore electrically connected to the return members 300a and 300b over the length from the one end to the other end of the second discharge electrode 134b in the longitudinal direction. An end of the return member 300a that is the end opposite to the second discharge electrode 134b is connected to a portion around the opening 131H in the top wall 131U of the chamber body 131M. An end of the return member 300b that is the end opposite to the second discharge electrode 134b is connected to a portion around the opening 131H in the top wall 131U of the chamber body 131M that is a portion opposite to the portion to which the return member 300a is connected. The return members 300a and 300b therefore electrically connect the second discharge electrode 134b to the chamber body 131M.

The chamber body 131M is electrically connected to the ground. The second discharge electrode 134b is therefore electrically connected to the ground via the spacers 187, the ground plate 137, the return members 300a and 300b, and the chamber body 131M. Note that the spacers 187 may be omitted, and in this case, the second discharge electrode 134b may be directly connected to each of the return members 300a and 300b. The return members 300a and 300b are preferably made of a material that is unlikely to chemically react with the laser gas, and examples of such electrically conductive materials may include copper and nickel.

The first discharge electrode 134a is fixed in an airtight manner to a surface of the electrically insulating plate 135 that is the surface facing the internal space of the discharge chamber 131 via a current introducing terminal 157, which is, for example, a bolt. The first discharge electrode 134a is therefore insulated from the chamber body 131M. The current introducing terminal 157 is electrically connected to the pulse compression circuit 150 and other circuit components, and ensures electrical continuity between the pulse compression circuit 150 and the first discharge electrode 134a.

The charger 141 is a high-voltage DC power supply that supplies the pulse compression circuit 150 with electric energy. A switch 151 is electrically connected to the charger 141 and controlled by the laser processor 190. When the switch 151 transitions from the off-state to the on-state, the electric energy from the charger 141 is supplied to the pulse compression circuit 150. The pulse compression circuit 150 generates a pulse-shaped high voltage from the electric energy stored in the charger 141, and applies the high voltage to the first discharge electrode 134a.

When the high voltage is applied to the first discharge electrode 134a, discharge occurs between the first discharge electrode 134a and the second discharge electrode 134b due to a difference in potential between the first discharge electrode 134a and the second discharge electrode 134b. The energy of the discharge excites the laser medium in the discharge chamber 131, and the excited laser medium emits light when transitioning to the ground state.

A preliminary ionization electrode 180 is provided on the ground plate 137 at one side of the second discharge electrode 134b via the spacer 187 and the end of the return member 300a. The preliminary ionization electrode 180 includes a dielectric pipe 181, a preliminary ionization inner electrode 183, and a preliminary ionization outer electrode 185.

The dielectric pipe 181 is so disposed that the longitudinal direction thereof coincides with the longitudinal direction of the second discharge electrode 134b, and is, for example, a cylindrical pipe. The dielectric pipe 181 is made, for example, of an aluminum oxide ceramic material or sapphire. The preliminary ionization inner electrode 183 is a rod-shaped electrode, is disposed inside the dielectric pipe 181, and extends along the longitudinal direction of the dielectric pipe 181. The preliminary ionization inner electrode 183 is made, for example, of copper or brass. The preliminary ionization outer electrode 185 is disposed between the dielectric pipe 181 and the second discharge electrode 134b, extends along the longitudinal direction of the dielectric pipe 181, and is fixed to the spacer 187. When the spacers 187 are omitted, the preliminary ionization outer electrode 185 is fixed to the second discharge electrode 134b. An end of the preliminary ionization outer electrode 185 is in contact with the outer circumferential surface of the dielectric pipe 181. Note that when corona discharge, which will be described later, occurs, a portion of the end of the preliminary ionization outer electrode 185 does not need to be in contact with the outer circumferential surface of the dielectric pipe 181.

The preliminary ionization inner electrode 183 is electrically connected to the pulse compression circuit 150 via a preliminary ionization capacitor that is not shown. The preliminary ionization outer electrode 185 is electrically connected to the second discharge electrode 134b via the ground plate 137, and is also electrically connected to the chamber body 131M via the ground plate 137 and the return members 300a and 300b. The preliminary ionization outer electrode 185 is therefore electrically connected to the ground. When the high voltage is applied to the space between the preliminary ionization inner electrode 183 and the preliminary ionization outer electrode 185 from the pulse compression circuit 150, corona discharge occurs in the vicinity of the end of the preliminary ionization outer electrode 185. The corona discharge assists stable generation of glow discharge that occurs between the first discharge electrode 134a and the second discharge electrode 134b.

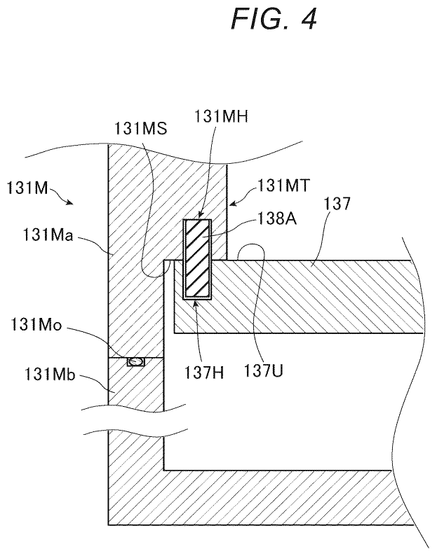

FIG. 4 is a descriptive diagram showing how the ground plate 137 and the chamber body 131M are positioned. The following description shows the state in which the ground plate 137 is fixed to the rear inner wall of the chamber body 131M, and the ground plate 137 is fixed in the same manner to the front inner wall of the chamber body 131M. The chamber body 131M can be divided into an upper section 131Ma and a lower section 131Mb, and an O-ring 131Mo serves as a seal not to create a space between the upper section 131Ma and the lower section 131Mb. The ground plate 137 has an upper surface 137U, a circumferential edge portion of which is provided with a recess 137H, which is recessed downward. The inner wall of the upper section 131Ma is provided with a protrusion 131MT, which protrudes toward the internal space, and a lower surface 131MS of the protrusion 131MT is provided with a recess 131MH, which is recessed upward, at the position where the recess 131MH faces the recess 137H. A positioning pin 138A is inserted into the recess 137H of the ground plate 137 and the recess 131MH of the chamber body 131M to restrict horizontal movement of the ground plate 137. Furthermore, the lower surface 131MS of the protrusion 131MT is in contact with the upper surface 137U of the ground plate 137, so that vertical movement of the ground plate 137 is restricted, and the ground plate 137 is fixed to the chamber body 131M, for example, with bolts that are not shown. The ground plate 137 is thus positioned with respect to the inner wall of the chamber body 131M.

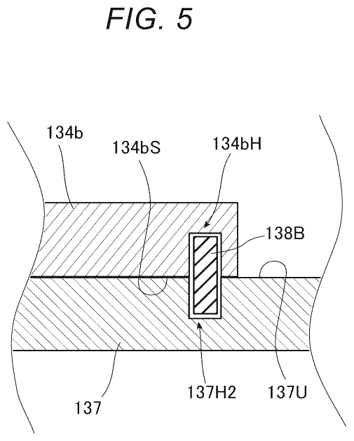

FIG. 5 is a descriptive diagram showing how the second discharge electrode 134b and the ground plate 137 are positioned. A lower surface 134bS of the second discharge electrode 134b is provided with a recess 134bH, which is recessed upward. The upper surface 137U of the ground plate 137 is provided with a recess 137H2, which is recessed downward, at the position where the recess 137H2 faces the recess 134bH. A positioning pin 138B is inserted into the recess 134bH of the second discharge electrode 134b and the recess 137H2 of the ground plate 137 to restrict horizontal movement of the second discharge electrode 134b. Furthermore, the configuration in which the upper surface 137U of the ground plate 137 is in contact with the lower surface 134bS of the second discharge electrode 134b restricts vertical movement of the second discharge electrode 134b, and fixes the second discharge electrode 134b to the ground plate 137, for example, with bolts that are not shown. The second discharge electrode 134b is thus positioned with respect to the ground plate 137. The second discharge electrode 134b is positioned with respect to the chamber body 131M via the ground plate 137 as described above.

A stabilizer 138a is provided at a side surface of the ground plate 137 that is the surface located on the side where the return member 300a is provided, as shown in FIG. 3. Furthermore, a guide 138b is provided at a lower surface of the ground plate 137 that is the surface located on the side where the return member 300b is provided. The stabilizer 138a and the guide 138b are members that rectify the flow of the laser gas in such a way that the flow of the laser gas is directed in an appropriate direction.

A crossflow fan 149 and a heat exchanger 148 are disposed at the side opposite to the second discharge electrode 134b with respect to the ground plate 137 in the internal space of the discharge chamber 131. The space of the discharge chamber 131 where the crossflow fan 149 and the heat exchanger 148 are disposed communicates with the space between the first discharge electrode 134a and the second discharge electrode 134b. The heat exchanger 148 is a radiator that is disposed next to the crossflow fan 149 and connected to a pipe which is not shown but through which a cooling medium flows. The crossflow fan 149 is connected to a motor 149a disposed outside the discharge chamber 131 as shown in FIG. 2, and rotated by the rotation produced by the motor 149a. When the crossflow fan 149 rotates, the laser gas with which the internal space of the discharge chamber 131 is filled circulates as indicated by the arrows in FIG. 3. That is, the crossflow fan 149 causes the laser gas to flow in the direction substantially perpendicular to the optical axis of the laser light between the first discharge electrode 134a and the second discharge electrode 134b. The laser gas flowing as described above causes the return member 300a to be located upstream in the flow of the laser gas, and the return member 300b to be located downstream in the flow of the laser gas. At least part of the circulating laser gas passes through the heat exchanger 148, which adjusts the temperature of the laser gas.

The laser gas is supplied from a laser gas supply source that is not shown via a pipe that is not shown. The laser gas in the discharge chamber 131 is caused to flow through a halogen filter that removes the F₂ gas from the laser gas and is otherwise treated, and the removed F₂ gas is exhausted by an exhaust pump that is not shown into the enclosure 110 through a pipe that is not shown.

The wall surface of the discharge chamber 131 is provided with a pair of windows 139a and 139b. The window 139a is located at one end of the discharge chamber 131 in the traveling direction of the laser light, and the window 139b is located at the other end in the traveling direction, so that the windows 139a and 139b sandwich the space between the first discharge electrode 134a and the second discharge electrode 134b. The windows 139a and 139b may each incline with respect to the traveling direction of the laser light by Brewster's angle, so that reflection of the laser light at the windows is suppressed. The oscillating laser light exits out of the discharge chamber 131 via the windows 139a and 139b, as will be described later. Since the pulse compression circuit 150 applies the pulse-shaped high voltage to the space between the first discharge electrode 134a and the second discharge electrode 134b as described above, the laser light is pulse laser light.

The line narrowing module 145 includes an enclosure 145a, a prism 145b, a grating 145c, and a rotary stage that is not shown, the latter three of which are disposed in the internal space of the enclosure 145a. An opening is formed in the enclosure 145a, and the enclosure 145a is connected via the opening to the rear side of the discharge chamber 131.

The prism 145b increases the beam width of the light that exits via the window 139a and causes the expanded light to be incident on the grating 145c. Furthermore, the prism 145b reduces the beam width of the light reflected off the grating 145c and causes the resultant light to return into the internal space of the discharge chamber 131 via the window 139a. The prism 145b is supported by the rotary stage that is not shown and rotated by the rotary stage. The rotation of the prism 145b can change the angle of incidence of the light to be incident on the grating 145c to select a wavelength of the light that returns from the grating 145c to the discharge chamber 131 via the prism 145b. FIG. 2 shows an example in which one prism 145b is disposed, and at least one prism only needs to be disposed.

The surface of the grating 145c is made of a high reflectance material, and a large number of grooves are provided at the surface at predetermined intervals. The cross-sectional shape of each of the grooves is, for example, a right triangle. When the light incident from the prism 145b on the grating 145c is reflected off the grooves, the light is diffracted in the direction according to the wavelength of the light. The grating 145c is disposed in the Littrow arrangement, which causes the angle of incidence of the light incident from the prism 145b on the grating 145c to be equal to the angle of diffraction of the diffracted light having a desired wavelength. Light having the desired wavelength and wavelengths therearound thus returns to the discharge chamber 131 via the prism 145b.

The output coupling mirror 147 is disposed in the internal space of an optical path tube 147a connected to the front side of the discharge chamber 131, and faces the window 139b. The output coupling mirror 147 transmits part of the laser light that exits via the window 139b toward the monitor module 160, and reflects the other part of the laser light to cause the light to return into the internal space of the discharge chamber 131 via the window 139b. The grating 145c and the output coupling mirror 147 thus constitute a Fabry-Perot laser resonator.

The monitor module 160 is disposed in the optical path of the laser light output via the output coupling mirror 147. The monitor module 160 includes an enclosure 161, a beam splitter 163, and a photosensor 165, the latter two of which are disposed in the internal space of the enclosure 161. An opening is formed in the enclosure 161, and the internal space of the enclosure 161 communicates via the opening with the internal space of the optical path tube 147a.

The beam splitter 163 transmits part of the laser light output via the output coupling mirror 147 toward the shutter 170, and reflects the other part of the laser light toward the light receiving surface of the photosensor 165. The photosensor 165 outputs a signal representing energy E of the laser light incident on the light receiving surface to the laser processor 190.

The laser processor 190 in the present disclosure is a processing apparatus including a storage 190a, which stores a control program, and a CPU (central processing unit) 190b, which executes the control program. The laser processor 190 is particularly configured or programmed to perform a variety of types of processing described in the present disclosure. The laser processor 190 further controls the entire gas laser apparatus 100.

The laser processor 190 transmits and receives a variety of signals to and from an exposure processor 230 of the exposure apparatus 200. For example, the laser processor 190 receives from the exposure processor 230 signals indicating a light emission trigger Tr, which will be described later, and target energy Et, and other pieces of information. The target energy Et is a target value of the energy of the laser light used in the exposure step. The laser processor 190 controls a charging voltage that charges the charger 141 based on the energy E received from the photosensor 165 and the target energy Et received from the exposure processor 230. Controlling the charging voltage controls the energy of the laser light. Furthermore, the laser processor 190 is electrically connected to the shutter 170 and controls opening and closing the shutter 170.

The shutter 170 is disposed in the optical path of the laser light in the internal space of an optical path tube 171, which communicates with an opening formed at a side of the enclosure 161 of the monitor module 160 that is the side opposite to the side to which the optical path tube 147a is connected. The internal spaces of the optical path tubes 171 and 147a, and the internal spaces of the enclosures 161 and 145a are filled with a purge gas supplied thereto. The purge gas contains an inert gas such as nitrogen (N₂). The purge gas is supplied from a purge gas supply source that is not shown via a pipe that is not shown. The optical path tube 171 communicates with the exposure apparatus 200 through an opening in the enclosure 110 and an optical path tube 600, which connects the enclosure 110 and the exposure apparatus 200 to each other. The laser light having passed through the shutter 170 enters the exposure apparatus 200.

The configurations of the return members 300a and 300b will next be described.

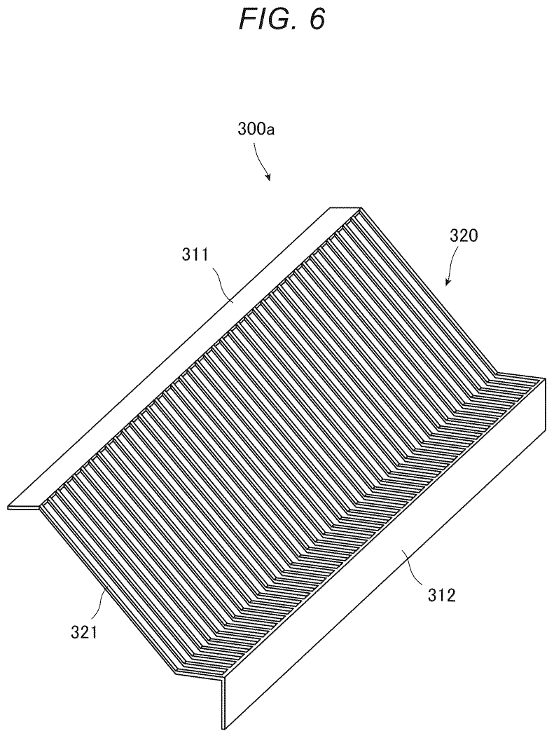

In the present example, the return members 300a and 300b have the same configuration, and only the return member 300a will therefore be described. FIG. 6 shows the return member 300a. The return member 300a is formed, for example, by punching and bending a single metal plate, and includes a plate-shaped first fixing section 311, a plate-shaped second fixing section 312, and a ladder section 320 connected to the first fixing section 311 and the second fixing section 312, as shown in FIG. 6. The metal plate to be punched and bent has a thickness ranging for example, from 1.0 mm to 1.2 mm.

The first fixing section 311 is a member having a substantially rectangular principal surface, and is attached to the top wall 131U of the chamber body 131M with the longitudinal direction of the first fixing section 311 aligned with the longitudinal direction of the first discharge electrode 134a. The principal surface of the first fixing section 311 is the surface specified by the end point of the leader line extending from the reference numeral 311 in FIG. 6. The second fixing section 312 has a shape that is substantially the same as the shape of the first fixing section 311, and is attached to the spacer 187 with the longitudinal direction of the second fixing section 312 aligned with the longitudinal direction of the second discharge electrode 134b.

The ladder section 320 is configured with multiple linear portions 321 arranged in parallel to each other. The linear portions 321 each have a width of, for example, approximately 1.0 mm. One end of each of the linear portions 321 is connected to the first fixing section 311, and the other end is connected to the second fixing section 312. In the present example, the return member 300a is formed by punching a single metal plate, as described above, so that the connection described above is not made by welding or brazing, but is metal continuity connection. Since the linear portions 321 are each connected to the first fixing section 311 and the second fixing section 312, the multiple linear portions 321 are arranged in parallel to each other along the longitudinal direction of the first discharge electrode 134a and the second discharge electrode 134b extending along the optical axis of the laser light. The width of the gap between the linear portions 321 adjacent to each other ranges, for example, from 19.0 mm to 19.5 mm, and the laser gas can pass through the gap as shown in FIG. 3.

A connection portion where the first fixing section 311 is connected to each of the linear portions 321 or a portion in the vicinity of the connection portion is bent, and the direction in which the linear portions 321 are arranged in parallel to each other is not parallel to the principal surface of the first fixing section 311. A connection portion where the second fixing section 312 is connected to each of the linear portions 321 or a portion in the vicinity of the connection portion is bent, and the direction in which the linear portions 321 are arranged in parallel to each other is not parallel to the principal surface of the second fixing section 312. Furthermore, the principal surface of the first fixing section 311 and the principal surface of the second fixing section 312 are not parallel to each other and incline with respect to each other by an angle of, for example, approximately 90 degrees.

### 2.2 Operation

The operation of the gas laser apparatus 100 according to Comparative Example will next be described.

In the state before the gas laser apparatus 100 outputs the laser light, the internal spaces of the optical path tubes 147a, 171, and 600 and the internal spaces of the enclosures 145a and 161 are filled with the purge gas from the purge gas supply source, which is not shown. The laser gas is supplied from the laser gas supply source, which is not shown, into the internal space of the discharge chamber 131. When the laser gas is supplied, the laser processor 190 controls the motor 149a to rotate the crossflow fan 149. The rotation of the crossflow fan 149 causes the laser gas to circulate in the internal space of the discharge chamber 131. In this process, the configuration in which the gap between the chamber body 131M and the electrically insulating plate 135 is sealed with the metal seal 133 prevents the laser gas from leaking out of the discharge chamber 131.

The crossflow fan 149 circulates the laser gas as indicated by the arrows in FIG. 3. In this process, the laser gas passes through the gaps between the linear portions 321 of the return member 300a provided at a position upstream from the first discharge electrode 134a and the second discharge electrode 134b in the flow of the laser gas. The laser gas then passes through the space between the first discharge electrode 134a and the second discharge electrode 134b, and passes through the gaps between the linear portions 321 of the return member 300b provided downstream from the first discharge electrode 134a and the second discharge electrode 134b in the flow of the laser gas.

When the laser processor 190 receives the signal indicating the target energy Et and the signal indicating the light emission trigger Tr from the exposure processor 230, the gas laser apparatus 100 is controlled to output the laser light. When the laser processor 190 receives the signal indicating the target energy Et, the laser processor 190 closes the shutter 170 and drives the charger 141. The laser processor 190 turns on the switch 151 in the pulse compression circuit 150. As a result, the current from the charger 141 flows to the pulse compression circuit 150, and the pulse-shaped high voltage is applied to the first discharge electrode 134a via the current introducing terminal 157. Note that the timing at which the high voltage is applied to the space between the preliminary ionization inner electrode 183 and the preliminary ionization outer electrode 185 is slightly earlier than the timing at which the high voltage is applied to the space between the first discharge electrode 134a and the second discharge electrode 134b. When the high voltage is applied to the space between the preliminary ionization inner electrode 183 and the preliminary ionization outer electrode 185, corona discharge occurs in the vicinity of the dielectric pipe 181 and the end of the preliminary ionization outer electrode 185, and ultraviolet light is radiated. When the laser gas between the first discharge electrode 134a and the second discharge electrode 134b is irradiated with the ultraviolet light, the laser gas between the first discharge electrode 134a and the second discharge electrode 134b is preliminarily ionized. After the preliminary ionization, when the high voltage is applied to the space between the first discharge electrode 134a and the second discharge electrode 134b as described above, primary discharge occurs between the first discharge electrode 134a and the second discharge electrode 134b.

Since the return members 300a and 300b are connected to the chamber body 131M, the current produced by the primary discharge flows to the chamber body 131M via the return members 300a and 300b.

The primary discharge excites the laser medium contained in the laser gas between the first discharge electrode 134a and the second discharge electrode 134b, and when the laser medium returns to the ground state, the laser medium emits light. The light resonates between the grating 145c and the output coupling mirror 147, and the light is amplified whenever passing through the discharge space between the first discharge electrode 134a and the second discharge electrode 134b in the internal space of the discharge chamber 131, resulting in laser oscillation. Part of the resonating laser light passes as the pulse laser light through the output coupling mirror 147 and travels to the beam splitter 163.

Part of the laser light having traveled to the beam splitter 163 is reflected off the beam splitter 163 and received by the photosensor 165. The photosensor 165 measures the energy E of the received laser light and outputs the signal indicating the energy E to the laser processor 190. The laser processor 190 controls the charging voltage in such a way that a difference ΔE between the energy E and the target energy Et falls within an allowable range, and after the difference ΔE falls within the allowable range, the laser processor 190 transmits a reception preparation completion signal, which indicates that the laser processor 190 is ready to receive the light emission trigger Tr, to the exposure processor 230.

Upon reception of the reception preparation completion signal, the exposure processor 230 transmits the light emission trigger Tr to the laser processor 190. When the laser processor 190 opens the shutter 170 in synchronization with the reception of the light emission trigger Tr, the laser light having passed through the shutter 170 enters the exposure apparatus 200. The laser light is, for example, pulse laser light having the center wavelength of 193 nm.

### 3. Problems

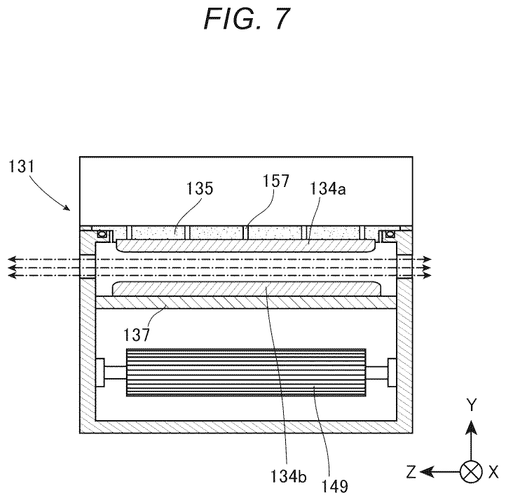

FIG. 7 is a cross-sectional view of the chamber apparatus 101 in Comparative Example taken along a plane parallel to the optical axis of the laser light. One of the factors that determine the service life of the chamber apparatus 101 is wear of the first discharge electrode 134a. The inventors have discovered through experiments that the current flowing from the second discharge electrode 134b to the chamber body 131M via the linear portions 321 near the opposite ends of the return members 300a and 300b in the longitudinal direction is smaller in some cases than the current flowing through the linear portions 321 near the centers of the return members 300a and 300b in the longitudinal direction. When the distribution of the return current flowing through the return members 300a and 300b is not uniform in the longitudinal direction described above, it can be estimated that the primary discharge is also not uniform along the longitudinal direction of the first discharge electrode 134a and the second discharge electrode 134b. When the primary discharge is not uniform, it is highly probable that the first discharge electrode 134a wears nonuniformly, so that there is a concern that the service life of the first discharge electrode 134a shortens due to the portions that wear out quickly.

A conceivable cause of the problem described above is that the current that should flow through the linear portions 321 near the opposite ends of the return members 300a and 300b in the longitudinal direction instead flows through the portion where the ground plate 137 is fixed to the inner wall of the chamber body 131M. It can therefore be predicted that the uniformity of the primary discharge can be improved by reducing the current flowing through the portion where the ground plate 137 is fixed to the inner wall of the chamber body 131M. It is therefore believed that the reduction can extend the life of the first discharge electrode 134a and hence the life of the chamber apparatus 101. The following embodiments therefore show examples of a long-life chamber apparatus for a laser 101 and gas laser apparatus 100.

### 4. Description of First Embodiment

The chamber apparatus 101 according to a first embodiment will next be described. Note that the same configurations as those described above have the same reference characters, and duplicate description of the same configurations will be omitted unless otherwise particularly described. In addition, in some of the drawings, some of the members are omitted or simplified in some cases for clarity, only some of the same elements have the same reference characters, and some other elements do not have reference characters in some cases.

### 4.1 Configuration

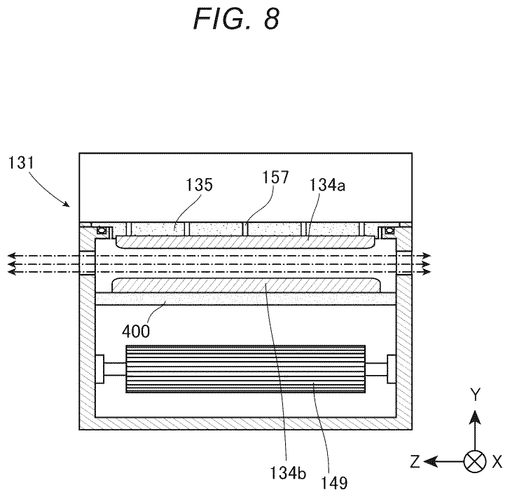

FIG. 8 shows the chamber apparatus 101 according to the present embodiment, as FIG. 7 does. The chamber apparatus 101 according to the present embodiment differs from that according to Comparative Example in that a support member 400, which is an insulator is provided in place of the ground plate 137. Therefore, in the chamber apparatus 101, the second discharge electrode 134b and the chamber body 131M are not electrically continuous with each other via the support member 400. The shape of the support member 400 is the same as that of the ground plate 137 in Comparative Example. The support member 400 is therefore fixed to the chamber body 131M in the same manner as the ground plate 137 in Comparative Example. The material of the support member 400 may be a ceramic material, for example, an aluminum oxide ceramic material.

### 4.2 Effects and Advantages

In the chamber apparatus 101 according to the present embodiment, no current flows from the second discharge electrode 134b to the support member 400. The longitudinal uniformity of the return current flowing through the return members 300a and 300b can therefore be improved. Improvement in the longitudinal uniformity of the return current can improve the longitudinal uniformity of the discharge between the first discharge electrode 134a and the second discharge electrode 134b. The uneven wear of the first discharge electrode 134a is therefore suppressed, so that the life of the gas laser apparatus 100 can be extended. Furthermore, since the shape of the support member 400 is the same as that of the ground plate 137 in Comparative Example, the structure that positions the second discharge electrode 134b can be maintained.

The return members 300a and 300b and the spacers 187 are preferably provided over the length from one end to the other end of the second discharge electrode 134b in the longitudinal direction, but not necessarily. The return members 300a and 300b and the spacers 187 may be extended slightly outward from the opposite ends of the second discharge electrode 134b in the longitudinal direction, or may not reach the opposite ends by a short length.

### 5. Description of Second Embodiment

The chamber apparatus 101 according to a second embodiment will be described. The same configurations as those described above have the same reference characters, and duplicate description of the same configurations will be omitted unless otherwise particularly described. In addition, in some of the drawings, some of the members are omitted or simplified in some cases for clarity, only some of the same elements have the same reference characters, and some other elements do not have reference characters in some cases.

### 5.1 Configuration

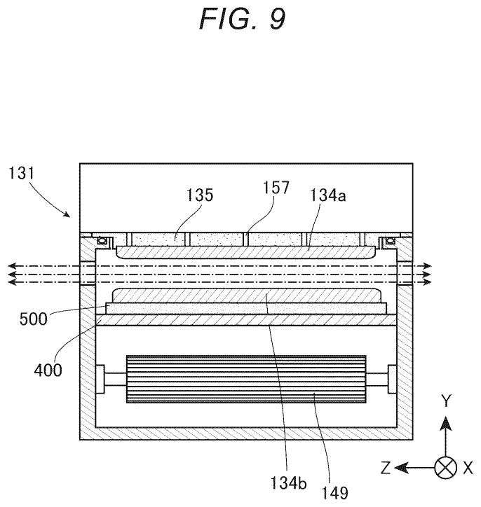

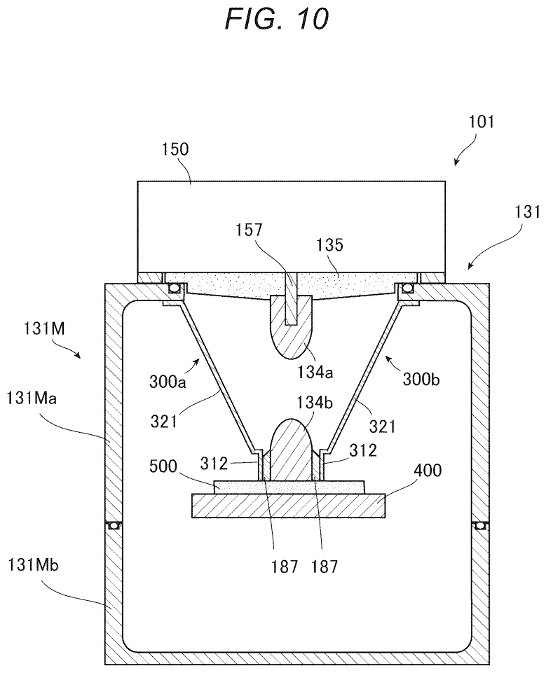

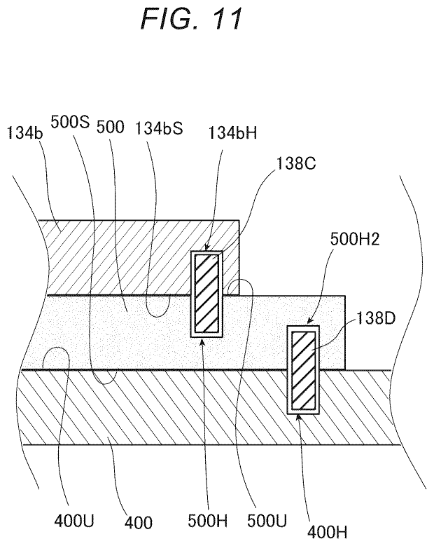

FIG. 9 shows the chamber apparatus 101 according to the present embodiment, as FIG. 7 does. FIG. 10 is a cross-sectional view of the chamber apparatus 101 according to the present embodiment taken along a plane perpendicular to the optical axis of the laser light. FIG. 11 shows how a placement member 500 and the support member 400 are positioned, and how the second discharge electrode 134b and the placement member 500 are positioned.

The support member 400 in the present embodiment primarily differs from that in the first embodiment in that the second discharge electrode 134b is supported via the placement member 500 configured with an insulator, as shown in FIG. 9. The material of the placement member 500 in the present embodiment may be a ceramic material, for example, an aluminum oxide ceramic material. The placement member 500 preferably has a thickness of 1.5 mm or greater in the Y direction. The support member 400 in the present embodiment may be configured with an insulator or may be electrically conductive. The material of the support member 400 may, for example, be metal such as aluminum. In addition, to make the distance between the first discharge electrode 134a and the second discharge electrode 134b equal to that in Comparative Example, the second discharge electrode 134b may be thinner in the Y-axis direction by the thickness of the placement member 500.

In the present embodiment, the return members 300a and 300b are not in contact with the support member 400, as shown in FIG. 10.

In the present embodiment, the second discharge electrode 134b is positioned with respect to the placement member 500. An upper surface 400U of the support member 400 is provided with a recess 400H, which is recessed downward, as shown in FIG. 11. A lower surface 500S of the placement member 500 is provided with a recess 500H2, which is recessed upward, at the position where the recess 500H2 faces the recess 400H. A positioning pin 138D is inserted into the recess 400H of the support member 400 and the recess 500H2 of the placement member 500 to restrict horizontal movement of the placement member 500. Furthermore, the configuration in which the lower surface 500S of the placement member 500 and the upper surface 400U of the support member 400 are in contact with each other restricts vertical movement of the placement member 500, and fixes the placement member 500 to the support member 400, for example, with bolts that are not shown. The placement member 500 is thus positioned with respect to the support member 400.

An upper surface 500U of the placement member 500 is provided with a recess 500H, which is recessed downward. The lower surface 134bS of the second discharge electrode 134b is provided with the recess 134bH, which is recessed upward, at the position where the recess 134bH faces the recess 500H. A positioning pin 138C is inserted into the recess 500H of the placement member 500 and the recess 134bH of the second discharge electrode 134b to restrict horizontal movement of the second discharge electrode 134b. Furthermore, the configuration in which the lower surface 134bS of the second discharge electrode 134b is in contact with the upper surface 500U of the placement member 500 restricts vertical movement of the second discharge electrode 134b, and fixes the second discharge electrode 134b to the placement member 500, for example, with bolts that are not shown. The second discharge electrode 134b is thus positioned with respect to the placement member 500.

### 5.2 Effects and Advantages

In the chamber apparatus 101 according to the present embodiment, the placement member 500 is configured with an insulator. Therefore, the current can primarily flow to the ground through the return members 300a and 300b, and the longitudinal uniformity of the return current flowing through the return members 300a and 300b can be improved. Improvement in the longitudinal uniformity of the return current can improve the longitudinal uniformity of the discharge between the first discharge electrode 134a and the second discharge electrode 134b. The uneven wear of the first discharge electrode 134a can therefore be suppressed, so that the life of the gas laser apparatus 100 can be extended. Furthermore, the placement member 500 can be realized in a shape that is smaller and is easier to process than the support member 400. Therefore, the second discharge electrode 134b is readily positioned, and the support member 400 can be produced from an inexpensive metal material such as aluminum, resulting in cost reduction.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined. The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A chamber apparatus for a laser configured to output laser light, the chamber apparatus comprising:
a chamber body;
a first discharge electrode disposed in an internal space of the chamber body and having a longitudinal direction aligned with an optical axis of the laser light;
a second discharge electrode so disposed in the internal space that the second discharge electrode faces the first discharge electrode and has a longitudinal direction aligned with the optical axis of the laser light;
a return member electrically connected to the chamber body and further electrically connected to the second discharge electrode over a length from one end to the other end thereof in the longitudinal direction; and
a support member fixed to the chamber body and supporting the second discharge electrode,
the second discharge electrode and the chamber body being not electrically continuous with each other via the support member.

2. The chamber apparatus for a laser according to claim 1, wherein
the support member is configured with an insulator.

3. The chamber apparatus for a laser according to claim 1, wherein
the support member supports the second discharge electrode via a placement member configured with an insulator.

4. The chamber apparatus for a laser according to claim 1, wherein
the first discharge electrode is a cathode, and the second discharge electrode is an anode.

5. The chamber apparatus for a laser according to claim 1, wherein
the return member includes multiple linear portions arranged in parallel to each other along the longitudinal direction of the second discharge electrode.

6. The chamber apparatus for a laser according to claim 1, wherein
the support member is positioned with a positioning pin with respect to the chamber body.

7. The chamber apparatus for a laser according to claim 3, wherein
the placement member has a thickness of 1.5 mm or greater.

8. A gas laser apparatus comprising:
a chamber apparatus for a laser configured to output laser light,
the chamber apparatus for a laser including
a chamber body,
a first discharge electrode disposed in an internal space of the chamber body and having a longitudinal direction aligned with an optical axis of the laser light,
a second discharge electrode so disposed in the internal space that the second discharge electrode faces the first discharge electrode and has a longitudinal direction aligned with the optical axis of the laser light,
a return member electrically connected to the chamber body and further electrically connected to the second discharge electrode over a length from one end to the other end thereof in the longitudinal direction, and
a support member fixed to the chamber body and supporting the second discharge electrode,
the second discharge electrode and the chamber body being not electrically continuous with each other via the support member.

9. An electronic device manufacturing method comprising:
outputting laser light generated by a gas laser apparatus to an exposure apparatus; and
exposing a photosensitive substrate to the laser light in the exposure apparatus to manufacture electronic devices,
the gas laser apparatus including a chamber apparatus for a laser configured to output the laser light, the chamber apparatus including
a chamber body,
a first discharge electrode disposed in an internal space of the chamber body and having a longitudinal direction aligned with an optical axis of the laser light,
a second discharge electrode so disposed in the internal space that the second discharge electrode faces the first discharge electrode and has a longitudinal direction aligned with the optical axis of the laser light,
a return member electrically connected to the chamber body and further electrically connected to the second discharge electrode over a length from one end to the other end thereof in the longitudinal direction, and
a support member fixed to the chamber body and supporting the second discharge electrode,
the second discharge electrode and the chamber body being not electrically continuous with each other via the support member.
